(19) United States
(12) Patent Application Publication
(10) Pub. No.: US 2013/0284510 A1
(43) Pub. Date: Oct. 31, 2013

(54) ELECTROMAGNETIC SHIELDING COVER AND DEVICE HAVING THE SAME

(71) Applicants: SHIH-PO LO, NEW TAIPEI CITY (TW); TAN-LUNG CHEN, NEW TAIPEI CITY (TW); CHING-FENG HSIEH, TAIPEI CITY (TW)

(72) Inventors: SHIH-PO LO, NEW TAIPEI CITY (TW); TAN-LUNG CHEN, NEW TAIPEI CITY (TW); CHING-FENG HSIEH, TAIPEI CITY (TW)

(73) Assignees: ASKEY COMPUTER CORP.; ASKEY TECHNOLOGY (JIANGSU) LTD.

(21) Appl. No.: 13/494,357

(22) Filed: Jun. 12, 2012

(30) Foreign Application Priority Data
Apr. 27, 2012 (TW) 101115140

(51) Int. Cl. H05K 9/00

(52) U.S. Cl. 174/377

(57) ABSTRACT

An electromagnetic shielding cover and a device having the same are introduced. The device comprises a casing and is coupled to a base having a printed circuit board on which an electronic component is mounted. The casing is defined with a receiving region. The electromagnetic shielding cover is disposed within the receiving region and coupled thereto. The electromagnetic shielding cover is marked with a plurality of peripheral folding lines. The electromagnetic shielding cover is folded along the peripheral folding lines by an angle to form a plurality of walls and a shielding space. Coupling the casing and the base together allows the electromagnetic shielding cover to shield an electronic component mounted on the circuit board and received in the shielding space, thereby shielding the electronic component from electromagnetic interference. The electronic component can be easily changed and tested during a rework process.

### CROSS-REFERENCE TO RELATED APPLICATION

This non-provisional application claims priority under 35 U.S.C. §119(a) on Patent Application No(s). 101115140 filed in Taiwan, R.O.C. on Apr. 27, 2012, the entire contents of which are hereby incorporated by reference.

### FIELD OF TECHNOLOGY

The present invention relates to electromagnetic shielding covers, and more particularly, to an electromagnetic shielding cover for use with a casing of an electronic device.

### BACKGROUND

Electronic devices are often susceptible to electromagnetic interference (EMI), and in consequence the performance of the electronic devices deteriorates. Examples of conventional electronic devices include smart mobile phones, tablet computers, and portable computers. As shown in FIG. 1, a shielding casing is a conventional tool of blocking EMI. The shielding casing essentially comprises a metal shielding frame 6 and a metal shielding cover 8. An assembly process of the shielding casing comprises the steps of: having a plurality of through holes 22 formed on a printed circuit board 2 with an electronic component 3 mounted thereon and positioned in a manner to surround the electronic component 3; providing a metal shielding frame 6 having a plurality of pins 62; passing the pins 62 through the through holes 22, respectively, and fastening the pins 62 through the through holes 22, respectively, to allow the printed circuit board 2 and the metal shielding frame 6 to be coupled together; and coupling the metal shielding cover 8 and the metal shielding frame 6 together so as to form the shielding casing for blocking EMI. A plurality of dents 64 (or bumps) is formed on the surface of the metal shielding frame 6. A plurality of bumps 82 (or dents) is formed on the surface of the metal shielding cover 8. The dents 64 correspond in position to the bumps 82, respectively. Coupling the dents 64 and the bumps 82 together results in the coupling together of the metal shielding frame 6 and the metal shielding cover 8.

To test or change the electronic component 3 of the printed circuit board 2, it is necessary to disassemble the shielding casing. The disassembly process of the shielding casing necessitates performing the aforesaid assembly process in reverse order. However, when carried out repeatedly or with an inappropriate applied force, the disassembly process of the shielding casing is likely to end up in deformation of the metal shielding cover 8, thereby preventing the reuse of the metal shielding cover 8 and incurring costs.

To shield the printed circuit boards 2 of different dimensions from EMI, it is necessary to make extra efforts to design and mold the metal shielding frames 6 of different dimensions and the metal shielding covers 8 of different dimensions, thereby adding to the manufacturing costs.

Accordingly, it is imperative to provide an electromagnetic shielding cover and an electronic device having the electromagnetic shielding cover to not only shield an electronic component of the electronic device from EMI but also change the electronic component at low costs.

### SUMMARY

It is an objective of the present invention to provide an electromagnetic shielding cover and a device having the electromagnetic shielding cover for shielding an electronic component from EMI.

Another objective of the present invention is to provide an electromagnetic shielding cover and a device having the electromagnetic shielding cover for changing and testing an electronic component easily.

Yet another objective of the present invention is to provide an electromagnetic shielding cover and a device having the electromagnetic shielding cover for cutting the manufacturing costs of a shielding casing.

In order to achieve the above and other objectives, the present invention provides a device having an electromagnetic shielding cover and coupled to a base having a printed circuit board having thereon an electronic component, the device comprising: a casing defined with a receiving region; and an electromagnetic shielding cover disposed within and coupled to the receiving region and marked with a plurality of peripheral folding lines, wherein the electromagnetic shielding cover is folded along the peripheral folding lines by an angle to form a plurality of walls and a shielding space for receiving therein the electronic component as soon as the casing and the base are coupled together, thereby shielding the electronic component with the electromagnetic shielding cover.

In order to achieve the above and other objectives, the present invention further provides an electromagnetic shielding cover coupled to a receiving region of a casing coupled to a base having a printed circuit board having thereon an electronic component, characterized in that: the electromagnetic shielding cover is marked with a plurality of peripheral folding lines, wherein the electromagnetic shielding cover is folded along the peripheral folding lines by an angle to form a plurality of walls and a shielding space for receiving therein the electronic component as soon as the casing and the base are coupled together, thereby shielding the electronic component with the electromagnetic shielding cover.

Compared with the prior art, the present invention provides an electromagnetic shielding cover and a device having the electromagnetic shielding cover. The electromagnetic shielding cover is folded along peripheral folding lines to form walls and a shielding space for receiving therein an electronic component as soon as a casing and a base are coupled together, thereby shielding the electronic component with the electromagnetic shielding cover. The electromagnetic shielding cover not only incurs low manufacturing costs, but also enables the electronic component to be changed and tested easily.

### BRIEF DESCRIPTION OF THE DRAWINGS

Objectives, features, and advantages of the present invention are hereunder illustrated with specific embodiments in conjunction with the accompanying drawings, in which:

FIG. 1 (PRIOR ART) is a structural schematic view of a conventional shielding casing;

FIGS. 2a through 2b are structural schematic views of an electromagnetic shielding cover according to the first embodiment of the present invention;

FIG. 3 is a cross-sectional schematic view of a base, a printed circuit board, an electronic component, and an electromagnetic shielding cover according to the first embodiment of the present invention;

FIG. 4 is a structural schematic view of a device having an electromagnetic shielding cover according to the first embodiment of the present invention;

FIGS. 5a, 5b are structural schematic views of the electromagnetic shielding cover of FIG. 4 with an adhesive layer;

FIG. 6 is a cross-sectional schematic view of a base coupled to a device having the electromagnetic shielding cover according to the second embodiment of the present invention; and

FIG. 7 is a structural schematic view of a device having the electromagnetic shielding cover according to the third embodiment of the present invention.

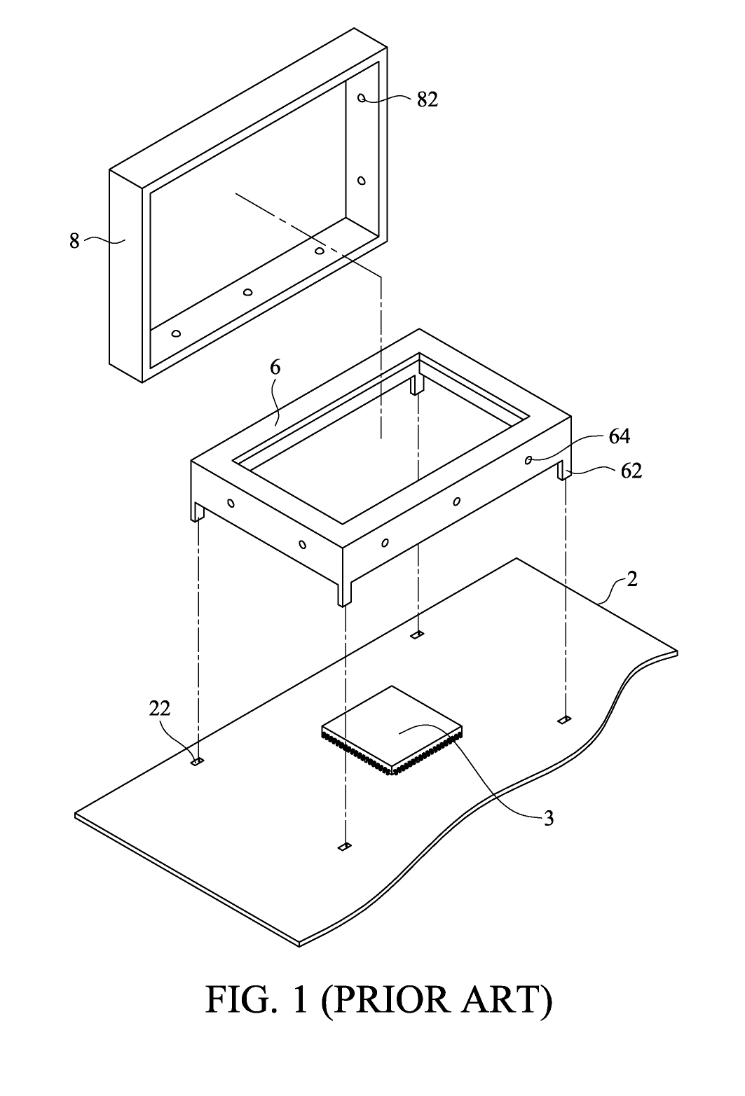

### DETAILED DESCRIPTION

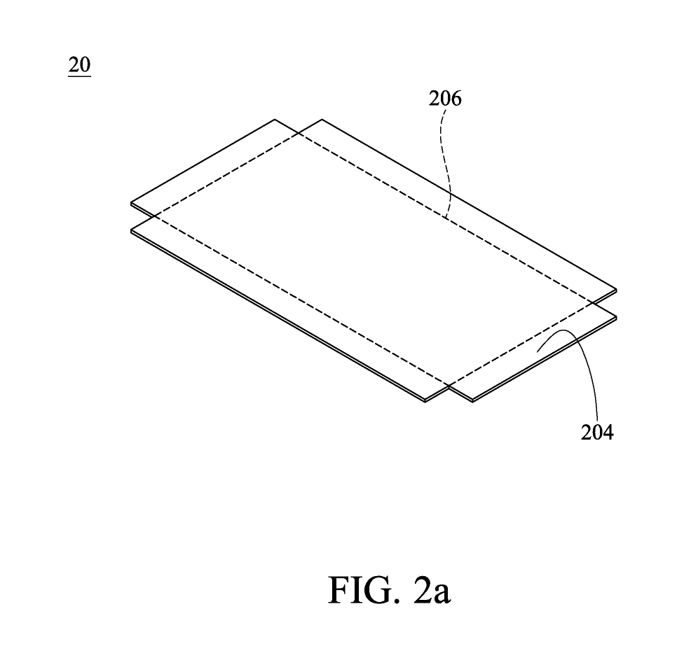

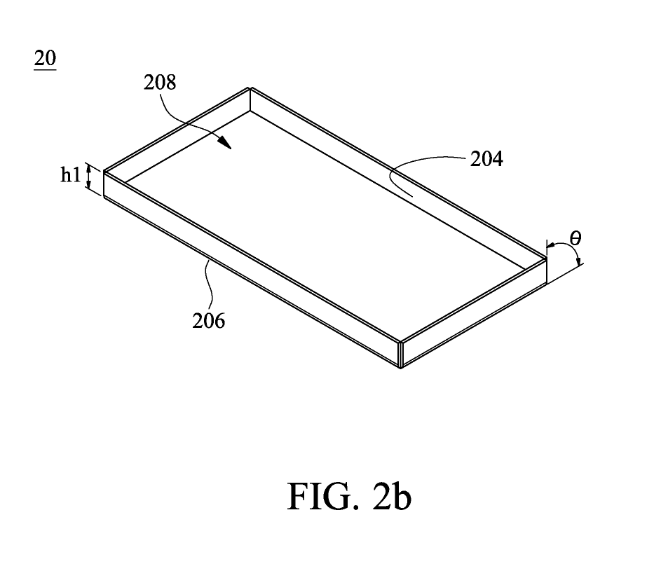

Referring to FIGS. 2a through 2b, there are shown structural schematic views of an electromagnetic shielding cover 20 according to the first embodiment of the present invention. FIG. 2a is a structural schematic view of the electromagnetic shielding cover 20 without a shielding space. FIG. 2b is a structural schematic view of the electromagnetic shielding cover 20 with a shielding space 208. As shown in the diagrams, the electromagnetic shielding cover 20 is marked with a plurality of peripheral folding lines 206 (shown in FIG. 2a), such that the electromagnetic shielding cover 20 is bent along the peripheral folding lines 206 by an angle θ to form a plurality of walls 204 with a height h1 and the shielding space 208 as shown in FIG. 2b.

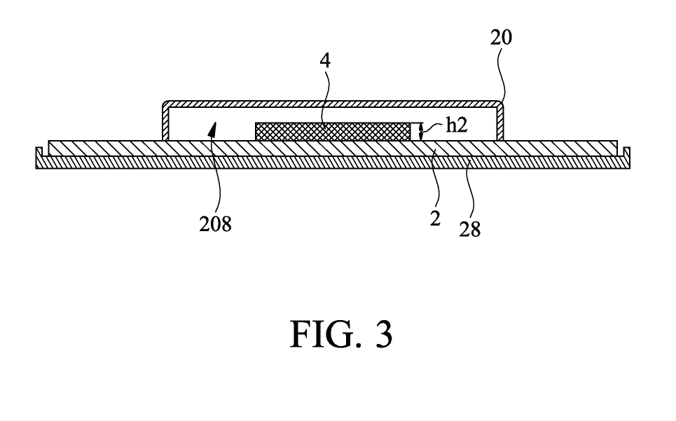

Referring to FIG. 3, there is shown a cross-sectional schematic view of a base 28, a printed circuit board 2, and an electronic component 4 mounted on the printed circuit board 2 and received in the shielding space 208 of the electromagnetic shielding cover 20 according to the first embodiment of the present invention. Referring to FIGS. 2b, 3, the electronic component 4 mounted on the printed circuit board 2 is received in the shielding space 208 of the electromagnetic shielding cover 20 and shielded by the electromagnetic shielding cover 20 from electromagnetic interference (EMI). Referring to FIG. 3, the electronic component 4 mounted on the printed circuit board 2 has a height h2.

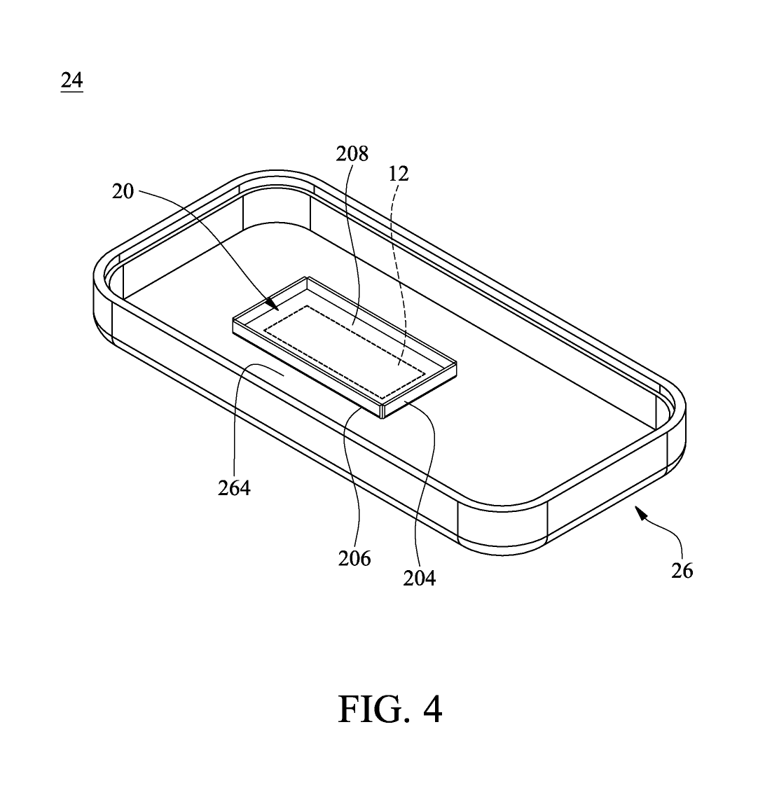

Referring to FIG. 4, there is shown a structural schematic view of a device 24 having the electromagnetic shielding cover 20 according to the first embodiment of the present invention. As shown in FIG. 3 and FIG. 4, the device 24 is intended to be coupled to the base 28 on which the printed circuit board 2 is mounted. The electronic component 4 is mounted on the printed circuit board 2. The device 24 comprises a casing 26 and the electromagnetic shielding cover 20. The electromagnetic shielding cover 20 corresponds in position to the electronic component 4 and is coupled to a receiving region 264 defined on the casing 26. The casing 26 is made of a plastic.

In this embodiment of the present invention, the angle θ is exemplified by 90 degrees, and the dimensions of the shielding space 208 are defined by the walls 204. After the casing 26 has been coupled to the base 28, the electronic component 4 is received in the shielding space 208 and shielded by the electromagnetic shielding cover 20 from EMI.

This embodiment and its accompanying drawings are illustrative rather than restrictive of the shape and dimensions of the walls 204 and the positions of the peripheral folding lines 206. The scope, functions, effects, and objectives of the present invention will be achieved, provided that the electromagnetic shielding cover 20 is large enough to shield the electronic component 4 from EMI. Specifically speaking, the height h1 of the walls 204 is larger than the height h2 of the electronic component 4 mounted on the printed circuit board 2, and the area of the printed circuit board 2 demarcated by the walls 204 is no less than the area of the printed circuit board 2 occupied by the electronic component 4, such that the electronic component 4 can be enclosed by the electromagnetic shielding cover 20.

The electromagnetic shielding cover 20 is made of a metal, such as copper, aluminum, or tin, such that electromagnetic wave propagates across the surface of the electromagnetic shielding cover 20 readily. In practice, the electromagnetic shielding cover 20 is made from a copper foil, an aluminum foil, or a tin foil.

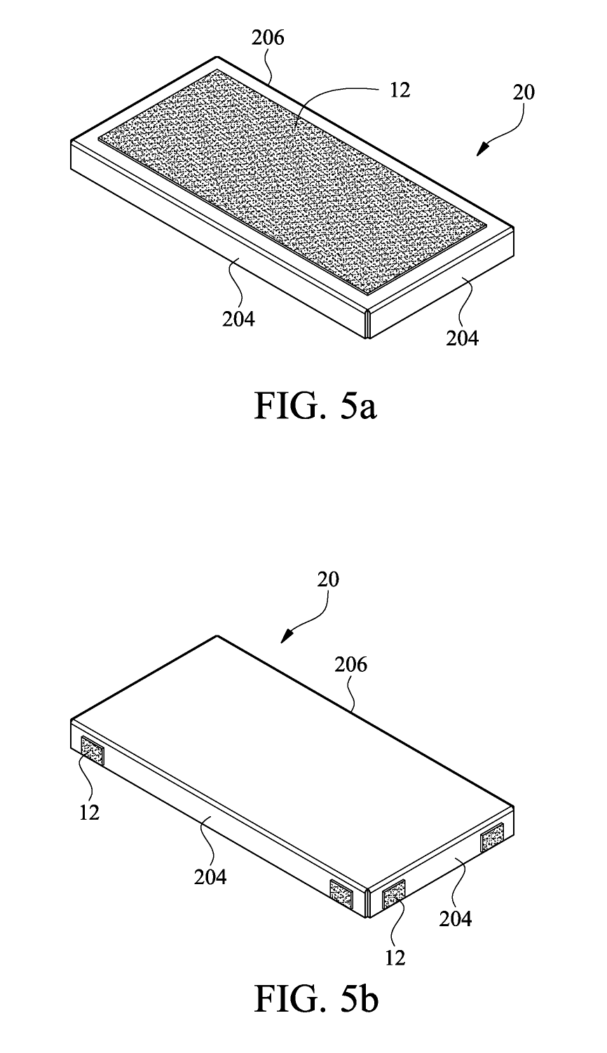

Referring to FIGS. 5a, 5b, there are shown structural schematic views of the electromagnetic shielding cover 20 with an adhesive layer 12. The adhesive layer 12 is disposed on the electromagnetic shielding cover 20. Alternatively, the adhesive layer 12 is disposed on the casing (not shown) rather than the electromagnetic shielding cover 20. Alternatively, the adhesive layer 12 is disposed on both the casing (not shown) and the electromagnetic shielding cover 20. Hence, the electromagnetic shielding cover 20 is adhered to and thereby coupled to the casing of the electronic device (not shown). For example, the adhesive layer 12 is an adhesive backing tape or a twin adhesive. Referring to FIG. 5a, the adhesive layer 12 is disposed on the electromagnetic shielding cover 20 for an illustrative purpose.

A point to note is that the thickness and dimensions of the adhesive layer 12 as well as the positions thereof on the electromagnetic shielding cover or the casing are subject to changes as needed. For example, the adhesive layer 12 can be disposed on the outer sides of the walls 204 (as shown in FIG. 5b), such that the electromagnetic shielding cover 20 is coupled to the casing 26 and corresponds in position to the electronic component.

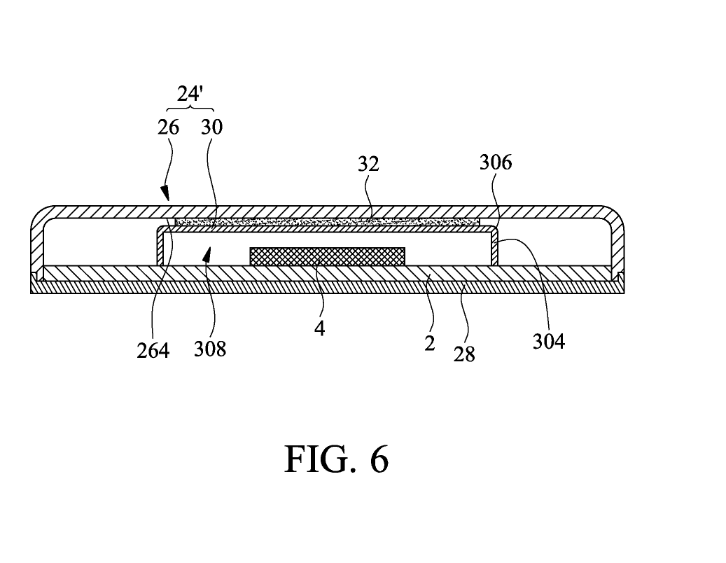

Referring to FIG. 6, there is shown a cross-sectional schematic view of a base coupled to a device 24′ having the electromagnetic shielding cover according to the second embodiment of the present invention. As shown in FIG. 6, the device 24′ is designed in a manner to shield the electronic component 4 of the printed circuit board 2 from EMI.

The device 24′ comprises the casing 26 and an electromagnetic shielding cover 30. The electromagnetic shielding cover 30 is adhered to the receiving region 264 of the casing 26 by means of an adhesive layer 32.

The electromagnetic shielding cover 30 is made of a metal, such as copper, aluminum, or tin, such that electromagnetic wave propagates across the surface of the electromagnetic shielding cover 30 readily. In practice, the electromagnetic shielding cover 30 is made from a copper foil, an aluminum foil, or a tin foil.

A plurality of walls 304 is formed by bending the electromagnetic shielding cover 30 along a plurality of peripheral folding lines 306 marked on the electromagnetic shielding cover 30. Due to the walls 304, the electromagnetic shielding cover 30 has a shielding space 308 formed therein. After the casing 26 has been coupled to the base 28, the electronic component 4 can be received in the shielding space 308 and thereby shielded from EMI by means of the electromagnetic shielding cover 30.

In this embodiment, the adhesive layer 32 is disposed between the electromagnetic shielding cover 30 and the casing 26 for coupling the casing 26 and the electromagnetic shielding cover 30 together. For example, the adhesive layer 32 is an adhesive backing tape.

For example, to put the device 24′ into use, a user has the electromagnetic shielding cover 30 adhered to the receiving region 264 of the casing 26, using the adhesive layer 32. Once the casing 26 and the base 28 are coupled together, the electromagnetic shielding cover 30 shields the electronic component 4 on the printed circuit board 2 to achieve EMI shielding. To change or test the electronic component 4 on the printed circuit board 2 easily, the user separates the casing 26 from the base 28 so as for the electronic component 4 to be exposed from the printed circuit board 2. Another advantage of the present invention is that, unlike its conventional counterpart which incurs high costs, the electromagnetic shielding cover 30 of the present invention incurs low costs, and thus even though the electromagnetic shielding cover 30 become not reusable after disassembly and rework as its conventional counterpart does, the electromagnetic shielding cover 30 adds to costs less than its conventional counterpart does.

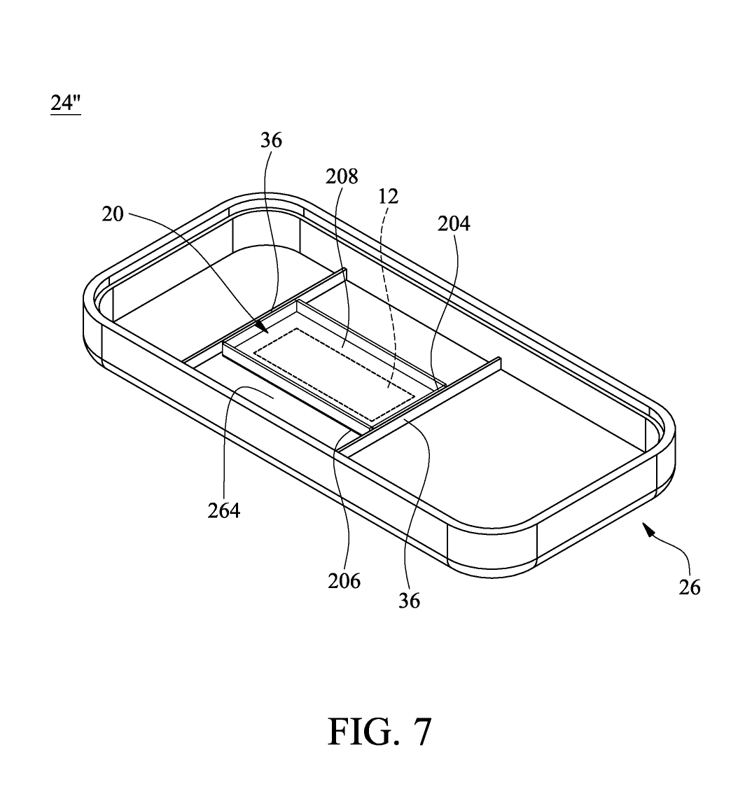

Referring to FIG. 7, there is shown a structural schematic view of a device 24″ having an electromagnetic shielding cover according to the third embodiment of the present invention. As shown in FIG. 7, the device 24″ comprises the casing 26, the electromagnetic shielding cover 20, and the adhesive layer 12. The casing 26 has a plurality of supporting elements 36 corresponding in position to the walls 204. The supporting elements 36 support the walls 204 and enable the electromagnetic shielding cover 20 to be positioned at a specific position in the receiving region 264 of the casing 26. For example, the supporting elements 36 are rib-like, block-shaped, and/or sheet-like. This embodiment is exemplified by the rib-like supporting elements 36.

In another embodiment, after the adhesive layer is put in place during the manufacturing process of the electromagnetic shielding cover, the electromagnetic shielding cover is cut according to the desirable dimensions and shape and then folded to form the walls in order to suit the electronic component-occupied area of the printed circuit board and the height of the electronic component. Hence, the present invention incurs less costs than the prior art which teaches developing, designing, and molding a metal shielding frame and a metal shielding cover for shielding an electronic component specifically.

A shielding test is performed at an electromagnetic wave frequency of 30 MHz˜1 GHz on three scenarios, namely the electromagnetic shielding cover of the present invention, a conventional shielding casing, and the absence of any shielding structure. The result of the shielding test indicates that, compared with the scenario of the absence of any shielding structure, the electromagnetic shielding cover of the present invention is as effective as the conventional shielding casing in EMI shielding.

Compared with the prior art, the present invention provides an electromagnetic shielding cover and a device having the electromagnetic shielding cover, such that the electromagnetic shielding cover can be folded directly along peripheral folding lines thereof to form a shielding space for receiving therein an electronic component as soon as the casing and the base are coupled together so as to shield the electronic component from electromagnetic interference, enable electronic component to be changed and tested easily, and cut the manufacturing costs of a shielding structure.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A device having an electromagnetic shielding cover and coupled to a base having a printed circuit board having thereon an electronic component, the device comprising:
a casing defined with a receiving region; and
an electromagnetic shielding cover disposed within and coupled to the receiving region and marked with a plurality of peripheral folding lines, wherein the electromagnetic shielding cover is folded along the peripheral folding lines by an angle to form a plurality of walls and a shielding space for receiving therein the electronic component as soon as the casing and the base are coupled together, thereby shielding the electronic component with the electromagnetic shielding cover.

2. The device of claim 1, wherein an area of the printed circuit board demarcated by the walls is no less than an area of the printed circuit board occupied by the electronic component, and the walls are higher than the electronic component on the printed circuit board.

3. The device of claim 1, wherein the casing has a plurality of supporting elements corresponding in position to the walls and adapted to support the walls when the electromagnetic shielding cover is disposed within the receiving region.

4. The device of claim 3, wherein the supporting elements are rib-like, block-shaped, and/or sheet-like.

5. The device of claim 1, further comprising an adhesive layer disposed on at least one of the casing and the electromagnetic shielding cover for allowing the electromagnetic shielding cover to be coupled to the receiving region of the casing by adhesion.

6. The device of claim 1, wherein the electromagnetic shielding cover is made of one of copper, aluminum, and tin.

7. An electromagnetic shielding cover coupled to a receiving region of a casing coupled to a base having a printed circuit board having thereon an electronic component, characterized in that: the electromagnetic shielding cover is marked with a plurality of peripheral folding lines, wherein the electromagnetic shielding cover is folded along the peripheral folding lines by an angle to form a plurality of walls and a shielding space for receiving therein the electronic component as soon as the casing and the base are coupled together, thereby shielding the electronic component with the electromagnetic shielding cover.

8. The electromagnetic shielding cover of claim 7, wherein an area of the printed circuit board demarcated by the walls is no less than an area of the printed circuit board occupied by the electronic component, and the walls are higher than the electronic component on the printed circuit board.

9. The electromagnetic shielding cover of claim 7, wherein the electromagnetic shielding cover is made of one of copper, aluminum, and tin.

10. The electromagnetic shielding cover of claim 7, wherein the electromagnetic shielding cover is adhered to the receiving region of the casing.
